(19) United States
(12) Patent Application Publication
(10) Pub. No.: US 2011/0227150 A1
(43) Pub. Date: Sep. 22, 2011

(54) SEMICONDUCTOR DEVICE AND METHOD FOR MANUFACTURING THE SAME

(75) Inventor: Katsumi HORITA, Hyogo-ken (JP)

(73) Assignee: Kabushiki Kaisha Toshiba, Tokyo (JP)

(21) Appl. No.: 12/886,444

(22) Filed: Sep. 20, 2010

(30) Foreign Application Priority Data
Mar. 19, 2010 (JP) 2010-065030

(51) Int. Cl. H01L 29/772; H01L 21/28

(52) U.S. Cl. 257/330; 438/586; 257/E21.19; 257/E29.242

(57) ABSTRACT

According to one embodiment, a semiconductor device includes a semiconductor layer of a first conductivity type, a first semiconductor region, a second semiconductor region, a gate electrode, a first electrode layer, an insulating member and a second electrode layer. The first semiconductor region of a second conductivity type is provided on a surface of the semiconductor layer. The second semiconductor region of the first conductivity type is selectively provided on a surface of the first semiconductor region. The gate electrode opposes the first semiconductor region and the second semiconductor region via a gate insulating film. The first electrode layer is electrically connected to the first semiconductor region and the second semiconductor region. The insulating member is embedded in a recess formed in a surface of the first electrode layer. The second electrode layer is provided on the first electrode layer and the insulating member.

### CROSS-REFERENCE TO RELATED APPLICATIONS

This application is based upon and claims the benefit of priority from the prior Japanese Patent Application No. 2010-065030, filed on Mar. 19, 2010; the entire contents of which are incorporated herein by reference.

### FIELD

Embodiments described herein relate generally to a semiconductor device and a method for manufacturing the same.

### BACKGROUND

In semiconductor device manufacturing methods, fine structures including gate electrodes and interconnection, as well as interlayer insulating films for insulating these elements, are provided on semiconductor substrates. Furthermore, electrode layers are provided on the surfaces of the semiconductor substrates having these fine structures.

However, when foreign bodies, such as particles generated within the semiconductor manufacturing apparatus, adhere to the semiconductor substrate, hole-like defects may occur in the affected portion. For example, if a hole-like defect occurs in a portion where the electrode layer provided on the fine structures on the semiconductor substrate is thin, the underlayer electrode or insulating film may be exposed, leading to operational problems. Therefore, a technology is required to flatten electrode surfaces by filling recesses and hole-like defects that occur as a result of the fine structures provided on the surfaces of the semiconductor substrates.

### BRIEF DESCRIPTION OF THE DRAWINGS

FIG. 1 is a schematic view illustrating a cross-section of a semiconductor device according to an embodiment;

FIG. 2 is a cross-sectional view schematically illustrating the manufacturing process for the semiconductor device according to the embodiment;

FIG. 3 is a cross-sectional view schematically illustrating the manufacturing process following FIG. 2;

FIG. 4 is a cross-sectional view schematically illustrating the manufacturing process following FIG. 3;

FIG. 5 is a cross-sectional view schematically illustrating the manufacturing process following FIG. 4; and

FIG. 6 is a cross-sectional view schematically illustrating the manufacturing process following FIG. 5.

### DETAILED DESCRIPTION

In general, according to one embodiment, a semiconductor device includes a semiconductor layer of a first conductivity type, a first semiconductor region, a second semiconductor region, a gate electrode, a first electrode layer, an insulating member and a second electrode layer. The first semiconductor region of a second conductivity type is provided on a surface of the semiconductor layer. The second semiconductor region of the first conductivity type is selectively provided on a surface of the first semiconductor region. The gate electrode opposes the first semiconductor region and the second semiconductor region via a gate insulating film. The first electrode layer is electrically connected to the first semiconductor region and the second semiconductor region. The insulating member is embedded in a recess formed in a surface of the first electrode layer. The second electrode layer is provided on the first electrode layer and the insulating member.

Embodiments of the invention will now be described with reference to the drawings. Note that in the following embodiments, components that are identical in the drawings are labeled with the same numerals and detailed descriptions of these components are omitted when appropriate. Differing components are described. Also, note that while a first conductivity type is described as being n-type and a second conductivity type is described as being p-type, the first conductivity type may be p-type and the second conductivity type may be n-type.

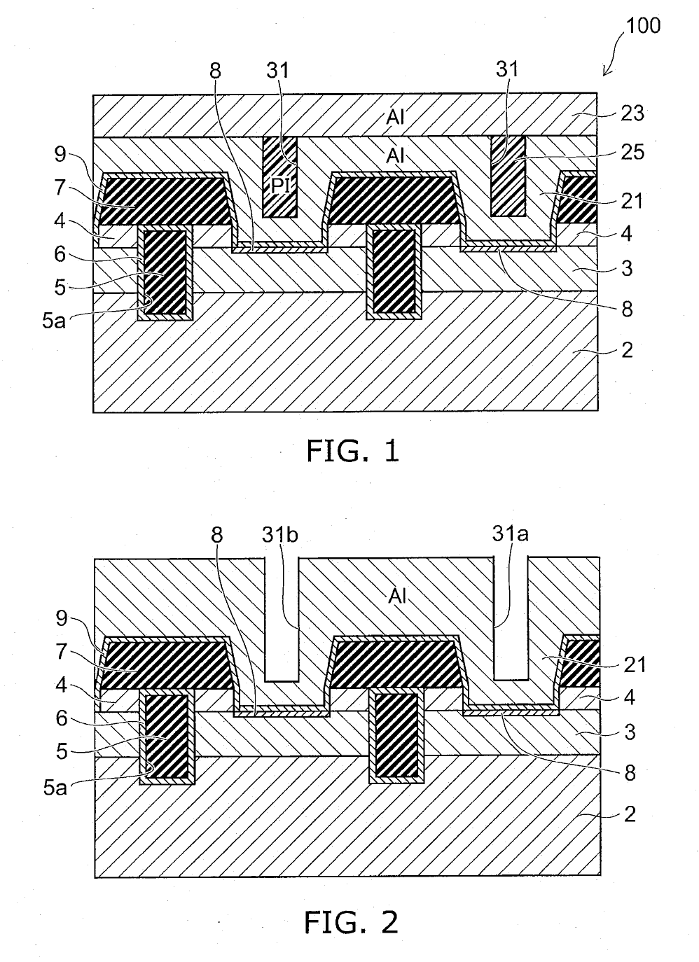

FIG. 1 is a schematic view illustrating a cross-section of a semiconductor device according to an embodiment. The semiconductor device according to this embodiment includes an n-type base layer 2 that is a semiconductor layer of a first conductivity type; a p-type base region 3, that is a first semiconductor region of a second conductivity type, provided on a surface of the n-type base layer 2; an n-type emitter region 4, that is a second semiconductor region of the first conductivity type, selectively provided on a surface of the p-type base region 3; and a gate electrode 5 that opposes the p-type base region 3 and the n-type emitter region 4 via a gate insulating film.

The semiconductor device further includes an emitter electrode 21, that is a first electrode layer, electrically connected to the p-type base region 3 and the n-type emitter region 4; an interlayer insulating film 7 that provides insulation between the emitter electrode 21 and the gate electrode 5; an insulating member 25 embedded in a recess 31 formed in a surface of the emitter electrode 21; and an emitter electrode 23, that is a second electrode layer, provided on the emitter electrode 21 and the insulating member 25.

In the semiconductor device according to this embodiment, the insulating member 25 is, for example, embedded over the p-type base region 3 between the interlayer insulating films 7.

Next, the semiconductor device illustrated in FIG. 1 is described in detail. The semiconductor device according to this embodiment is an IGBT that is, for example, provided on a silicon substrate.

The p-type base region 3 is provided on the surface of the n-type base layer 2. Furthermore, the n-type emitter region 4 and a p-type base contact 8 with a high carrier concentration are selectively provided on the surface of the p-type base region 3. Note also that a p-type collector layer (not shown) is proved under the n-type base layer 2.

Furthermore, trenches 5a are formed penetrating from a surface of the n-type emitter region 4, through the n-type emitter region 4 and the p-type base region 3, to communicate with the n-type base layer 2; and the gate electrode 5 is provided in the trenches 5a. The gate electrode 5 is insulated from the n-type emitter region 4, the p-type base region 3, and the n-type base layer 2 by a gate insulating film 6.

The interlayer insulating film 7 is provided over the gate electrode 5 and the emitter regions 4, insulating the gate electrode 5 from the emitter electrode 21. The emitter electrode 21 is provided on the interlayer insulating film 7, side surfaces of the emitter regions 4, and a surface of the p-type base contact 8, via a barrier layer 9. The barrier layer 9 can be formed using TiW, for example, and the emitter regions 4 and the p-type base contact 8 are electrically connected to the emitter electrode 21 via the barrier layer 9. Furthermore, an emitter electrode 23 is provided on a surface of the emitter electrode 21.

As illustrated in FIG. 1, a recess 31 is formed in the surface of the emitter electrode 21, which is formed so as to cover the interlayer insulating film 7 that protrudes above the gate electrode 5 and the n-type emitter region 4. The recess 31 is positioned over the p-type base contact 8 that is provided between the interlayer insulating films 7. The position over the p-type base contact 8 is also over the p-type base region 3. For example, in the case that the p-type base contact 8 is not provided, the emitter electrode 21 is provided on the surface of the p-type base region 3 that is exposed between the interlayer insulating films 7, via the barrier layer 9.

The insulating member 25 is embedded in the recess 31. Furthermore, by providing the emitter electrode 23 on the surface of the emitter electrode 21, the emitter electrode 23 can be formed in a state in which the surface of the emitter electrode 23 does not have a cavity corresponding to the recess 31. Polyimide, which is an insulating resin, can be used as the insulating member 25, for example.

The recess 31 may occur due to a step between the interlayer insulating films 7 and the p-type base contact 8, or may occur when a foreign body becomes adhered during the forming of the emitter electrode 21. Furthermore, the recess 31 may occur as a result of both the steps between the interlayer insulating films 7 and the p-type base contact 8, and a foreign body adhered to the emitter electrode 21.

The emitter electrode 21 and the emitter electrode 23 may be formed from the same metal material, or different metal materials may be used. For example, aluminum (Al) can be used for the emitter electrode 21 and the emitter electrode 23.

For example, in the semiconductor device manufacturing process according to this embodiment, a barrier layer 9 formed from titanium tungsten (TiW) and an emitter electrode 21 formed from aluminum (Al) can be provided on the surface of the p-type base contact 8 and the interlayer insulating film 7 using a sputtering method.

Here, foreign bodies resulting from dust may adhere to the surface of the semiconductor substrate in the sputtering equipment during the TiW—Al sputtering, and may be included in the emitter electrode 21. Adhered foreign bodies are removed by etching the surface of the emitter electrode 21, but this etching results in hole-like defects being formed in the surface of the emitter electrode 21.

For example, when the above-described hole-like defects are formed, the barrier layer 9 and/or the p-type base contact 8 under the emitter electrode 21 may be exposed. Additionally, mobile ions of sodium (Na) or the like may penetrate the gate insulating film 6, causing an increase in channel leakage current. Consequently, a problem of a loss of reliability of the semiconductor device may occur.

Furthermore, the above-described hole-like defects can, for example, occur easily above the p-type base contact 8 that is sandwiched between the interlayer insulating films 7. Due to the combined effects of the step between the interlayer insulating films 7 and the p-type base contact 8 and the foreign bodies adhered to the emitter electrode 21, the following problems occur: the hole-like defect is made deeper, mobile ions more easily penetrate, and yield suffers due to being judged as “poor” during appearance inspection.

In the semiconductor device according to this embodiment, the recess 31 formed in the emitter electrode 21 above the p-type base contact 8 between the interlayer insulating films 7 is filled with the insulating member 25. Thereby, the surface of the emitter electrode 23 provided on the emitter electrode 21 can be flattened. At other portions too, hole-like defects resulting from the adherence of foreign bodies during the forming of the emitter electrode 21 can be simultaneously filled using the insulating member 25.

Accordingly, a highly reliable semiconductor device can be provided in which the surface of the emitter electrode 23 has been flattened. Note that “flat” is used here to indicate a state in which local cavities or hole-like defects have been filled.

Next, a manufacturing process for the semiconductor device according to the embodiment is described. FIG. 2 to FIG. 6 are cross-sectional views schematically illustrating the manufacturing process for the semiconductor device.

The manufacturing process for the semiconductor device according to this embodiment includes: providing, on an interlayer insulating film 7, an emitter electrode 21 that is electrically connected to a p-type base region 3 via a p-type base contact 8 and electrically connected to a n-type emitter region 4; forming an insulating film 25a on a surface of the emitter electrode 21; flattening the surface of the emitter electrode 21 by leaving the insulating film 25a in a recess 31 that has formed in the surface of the emitter electrode 21; and providing an emitter electrode 23 on the surface of the emitter electrode 21.

FIG. 2 is cross-sectional view schematically illustrating a state in which the interlayer insulating film 7 is provided on the gate electrode 5, which has a trench structure, and the emitter electrode 21 is provided on the p-type base contact 8 that is sandwiched between the interlayer insulating films 7.

Specifically, FIG. 2 illustrates a state subsequent to laminating an aluminum (Al) layer that forms the emitter electrode 21 and a titanium tungsten (TiW) layer that forms the barrier layer 9 using, for example, a sputtering method and then etching to remove foreign bodies from the surface of the emitter electrode 21. A recess 31a is formed above the p-type base contact 8 between the interlayer insulating films 7.

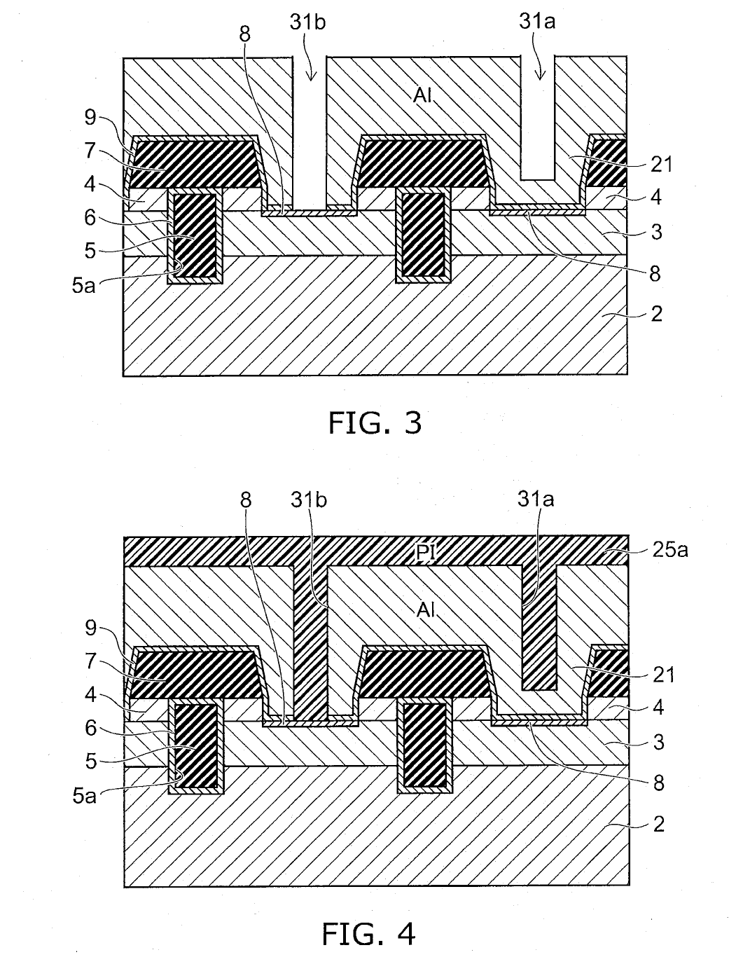

For example, as illustrated by a recess 31b in FIG. 3, in addition to the case of the recess 31a, at times, defects due to foreign bodies are superimposed, leading to a large quantity of the emitter electrode 21 being removed and exposing the p-type base contact 8 underneath.

FIG. 4 illustrates a state in which the recesses 31a and 31b are filled by forming an insulating film 25a on the surface of the emitter electrode 21.

A polyimide film can be used as the insulating film 25a, for example. The polyimide film can be formed by spin coating liquid polyimide on the surface of the emitter electrode 21. Additionally, besides a polyimide film, a film including SiO₂ such as spin-on glass (SOG) can be used.

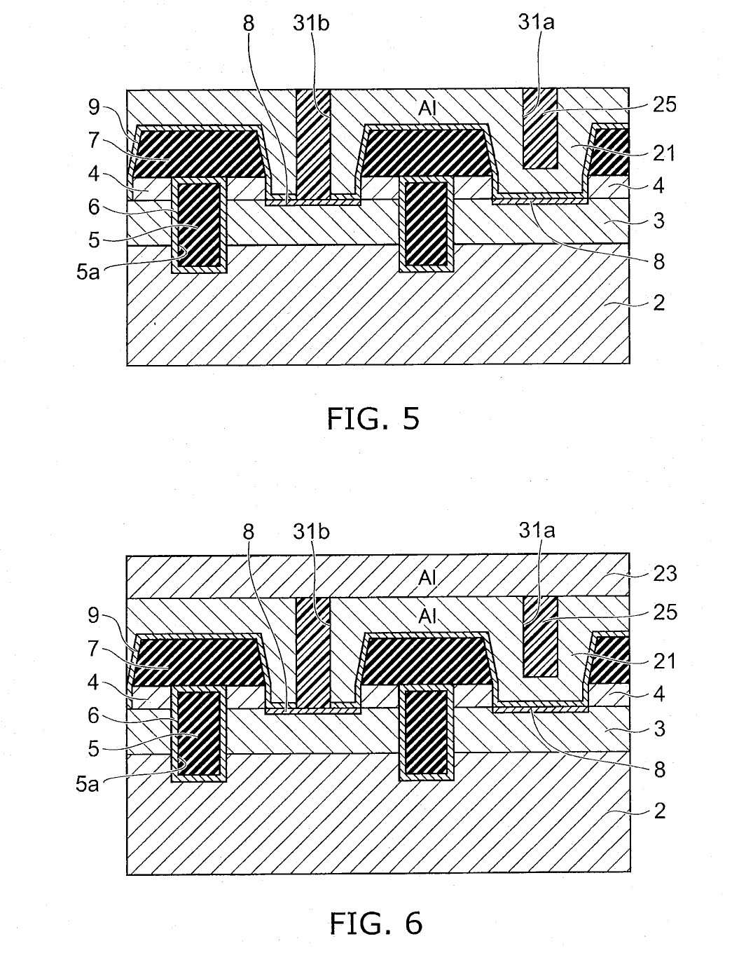

FIG. 5 illustrates a state in which the portion of the insulating film 25a on the surface of the emitter electrode 21 has been removed while the portions that are to become the insulating members 25 are left in the recesses 31a and 31b.

The insulating film 25a formed on the surface of the emitter electrode 21 can be removed using, for example, a dry etching method. Additionally, the insulating film 25a formed on the surface of the emitter electrode 21 may be flattened using a Chemical Mechanical Polish (CMP) method.

FIG. 6 illustrates a state in which the emitter electrode 23 has been formed on the emitter electrode 21 after removal of the insulating film 25a. The emitter electrode 23 can be provided by laminating Al on the emitter electrode 21 using, for example, a sputtering method.

As described above, in the manufacturing method of the semiconductor device according to the present embodiment, by filling open portions in the emitter electrode 21, specifically the recess 31 and the hole-like defects resulting from foreign bodies, with the insulating member 25 and, furthermore, providing the emitter electrode 23, the penetration of mobile ions can be prevented and the reliability of the semiconductor device can be enhanced. Furthermore, the number rejected products due to hole defects found in the inspection of appearance can be reduced.

Furthermore, if a thick electrode is formed on the emitter electrode 23 using, for example, a plating method, corrosion by the etching liquid used in pre-processing and/or penetration of the plating liquid can be prevented, the number rejected products due to hole defects found in the inspection of appearance can be reduced, and reliability can be enhanced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1. A semiconductor device comprising:
a semiconductor layer of a first conductivity type;
a first semiconductor region of a second conductivity type, provided on a surface of the semiconductor layer;
a second semiconductor region of the first conductivity type, selectively provided on a surface of the first semiconductor region;
a gate electrode opposing the first semiconductor region and the second semiconductor region via a gate insulating film;
a first electrode layer electrically connected to the first semiconductor region and the second semiconductor region;
an insulating member embedded in a recess formed in a surface of the first electrode layer; and
a second electrode layer provided on the first electrode layer and the insulating member.

2. The device according to claim 1, wherein the insulating member is embedded above the first semiconductor region between interlayer insulating films that insulate the gate electrode from the first electrode layer.

3. The device according to claim 2, wherein the gate electrode is provided in a trench reaching from a surface of the second semiconductor region to the semiconductor layer.

4. The device according to claim 3, wherein the interlayer insulating films extend in a direction from a surface of the gate electrode and the surface of the second semiconductor region to the first electrode layer.

5. The device according to claim 1, wherein the recess is a hole formed after removing foreign bodies which adhere to the first electrode layer.

6. The device according to claim 1, wherein the insulating member is an insulating resin.

7. The device according to claim 1, wherein the insulating member is made of polyimide.

8. The device according to claim 1, wherein the insulating member include silicon dioxide (SiO₂).

9. The device according to claim 1, wherein the first electrode layer and the second electrode layer include an identical metal material.

10. The device according to claim 1, wherein the first electrode layer and the second electrode layer include aluminum (Al).

11. The device according to claim 1, wherein the first electrode layer include a titanium tungsten (TiW) layer connected to the first semiconductor region and the second semiconductor region and an Al layer provided on the TiW layer.

12. The device according to claim 1, wherein the surface of the first electrode layer including a surface of the insulating member embedded in the recess is flat.

13. A manufacturing method for a semiconductor device including:
a semiconductor layer of a first conductivity type;
a first semiconductor region of a second conductivity type, provided on a surface of the semiconductor layer;
a second semiconductor region of the first conductivity type, selectively provided on a surface of the first semiconductor region; and
a gate electrode opposing the first semiconductor region and the second semiconductor region via a gate insulating film,
the method comprising:
forming a first electrode layer electrically connected to the first semiconductor region and the second semiconductor region;
forming an insulating film on a surface of the first electrode layer;
flattening the surface of the first electrode layer leaving the insulating film in a recess formed in the surface of the first electrode layer; and
forming a second electrode layer on the surface of the first electrode layer.

14. The method according to claim 13, wherein the first electrode layer includes a structure having a TiW layer and a Al layer sequentially stacked, the TiW layer and the Al layer formed using a sputtering method.

15. The method according to claim 13, further comprising:
etching the surface of the first electrode layer to remove foreign bodies.

16. The method according to claim 13, wherein the insulating layer is formed by spin coating polyimide.

17. The method according to claim 13, wherein the insulating film is formed by spin coating SOG containing SiO₂.

18. The method according to claim 13, wherein the insulating film formed on the surface of the first electrode layer is removed by dry etching and is left in the recess.

19. The method according to claim 13, wherein the insulating film is removed by CMP (Chemical Mechanical Polish), the surface of the first electrode layer is flattened and the insulating film is left in the recess.

20. The method according to claim 13, wherein a second electrode layer containing Al is formed by using a sputtering method on the flattened first electrode layer and the recess with the left insulating film.
